(19) United States
(12) Patent Application Publication
(10) Pub. No.: US 2026/0282274 A1
(43) Pub. Date: Sep. 17, 2026

(54) COLDPLATE FOR LIQUID COOLING OF AN ELECTRONIC COMPONENT

(71) Applicant: NVIDIA Corporation, Santa Clara, CA (US)

(72) Inventors: Zhiqiang Yu, Shenzhen (CN); Hongren Chen, Shenzhen (CN); Yuanzhuo Mei, Shenzhen (CN); Jun Li, Shenzhen (CN); Zhenguang Huang, Shenzhen (CN); Dongmei Niu, Shenzhen (CN)

(21) Appl. No.: 19/087,014

(22) Filed: Mar. 21, 2025

(30) Foreign Application Priority Data
Mar. 12, 2025 (CN) 2025102979838

(51) Int. Cl. H05K 7/20; H05K 7/14

(52) U.S. Cl. CPC H05K 7/20254; H05K 7/1424; H05K 7/20272

(57) ABSTRACT

Examples of a coldplate for thermal management of electronic components are disclosed. In an example, a coldplate apparatus includes a body having a top structure and a sidewall, wherein the top structure and the sidewall form a receiving channel configured to be disposed over an electronic component, wherein the sidewall of the body includes a first opening, a second opening, and a sidewall conduit, wherein the sidewall conduit is configured to allow liquid to flow between the first opening and the second opening, and wherein the top structure includes a plurality of topside conduits that are configured to allow liquid to flow between the first opening and the second opening.

### FIELD

The present disclosure relates to thermal management of electronic parts such as pluggable transceiver modules, including liquid cooling of electronic parts.

### BACKGROUND

In many modern computing systems, it is desirable to apply liquid cooling to electronic components to improve performance and longevity of the electronic components. Network interface cards such as converged Peripheral Component Interconnect (PCI) and PCI express (PCIe) cards often implement these electronic components, such as graphics processing units (GPUs), data processing units (DPUs), and/or network interconnection components. Liquid cooling can be applied to these electronic components within the network interface cards (e.g., PCIe cards), and liquid cooling of an electronic component can be accomplished via a coldplate through which liquid flows to draw heat away from the electronic component. The formfactor of network interface cards can impose design limitations on such coldplates.

### SUMMARY

Examples of a coldplate for thermal management of electronic components are disclosed. In an example, a coldplate apparatus includes a body having a top structure and a sidewall, wherein the top structure and the sidewall form a receiving channel configured to be disposed over an electronic component, wherein the sidewall of the body includes a first opening, a second opening, and a sidewall conduit, wherein the sidewall conduit is configured to allow liquid to flow between the first opening and the second opening, and wherein the top structure includes a plurality of topside conduits that are configured to allow liquid to flow between the first opening and the second opening.

In an example, the top structure is a rectangular top structure and the sidewall extends down from three edges of the rectangular top structure to form the receiving channel.

In an example, the sidewall includes a first side portion, a second side portion, and an end portion, and at least one of the plurality of topside conduits connects the sidewall conduit in the first side portion of the sidewall to the sidewall conduit in the second side portion of the sidewall.

In an example, the sidewall conduit in the first side portion of the sidewall and the sidewall conduit in the second side portion of the sidewall are parallel to each other and orthogonal to the plurality of topside conduits.

In an example, the receiving channel is rectangular in shape, closed on three sides, and open on one side.

In an example, the first opening in the sidewall and the second opening in the sidewall are located at an end of the coldplate that corresponds to the open side of the receiving channel.

In an example, at least some of the topside conduits are separated by one or more ribs of the top structure.

In an example, the electronic component is a rectangular shaped electronic component.

In an example, the electronic component is a pluggable transceiver module, and wherein the receiving channel is configured to be disposed over a cage that receives the pluggable transceiver module.

In an example, the pluggable transceiver module is an Octal Small Form Factor Pluggable (OSFP) transceiver module, and the cage is an OSFP cage.

In an example, the cage includes an opening at a top surface, and the top structure of the body includes a pedestal on a bottom surface of the top structure that fits within the opening at the top surface of the cage.

In an example, at least some of the topside conduits are separated by one or more ribs of the top structure, wherein the topside conduits are only positioned above the pedestal.

In an example, the receiving channel formed by the body and sidewall is coupled with a cage of a network interface.

In an example, the top structure of the body has a maximum height of about 1.8 millimeters.

In an example, the body includes a bottom piece attached to a top piece.

An example of a coldplate apparatus for performing thermal management of a pluggable electronic component is disclosed. The coldplate apparatus includes a body having a top structure and a sidewall, wherein the top structure and the sidewall form a receiving channel configured to be disposed over at least three sides of a cage that is configured to receive the pluggable electronic component, wherein the sidewall of the body includes a first opening, a second opening, and a sidewall conduit that is configured to allow liquid to flow between the first opening and the second opening, and wherein the top structure includes a plurality of topside conduits that are configured to allow liquid to flow between the first opening and the second opening.

In an example, the sidewall is configured to be coupled with two sidewalls of the cage and the top structure is configured to be coupled with a top of the cage.

In an example, the cage is an OSFP cage.

An example of a network interface card is disclosed. The network interface card includes a circuit board, a serial bus interface coupled to the circuit board, a cage attached to the circuit board and configured to receive a pluggable electronic component, a coldplate including a body having a rectangular top structure and a sidewall extending down from three edges of the top structure, wherein the top structure and the sidewall form a receiving channel to couple with the cage, wherein the sidewall of the body includes a first opening, a second opening, and a sidewall conduit that is configured to allow liquid to flow between the first opening and the second opening, and wherein the top structure includes a plurality of topside conduits that are configured to allow liquid to flow between the first opening and the second opening.

In an example, the cage is an OSFP cage.

Other aspects in accordance with the invention will become apparent from the following detailed description, taken in conjunction with the accompanying drawings, illustrated by way of example of the principles of the invention.

### BRIEF DESCRIPTION OF THE DRAWINGS

FIG. 1 is a side view of an example of a network interface card.

FIG. 2A is a perspective view of a cage of a network interface that is attached to a circuit board of a network interface card.

FIG. 2B is a perspective view of the cage from FIG. 2A and a pluggable module inserted into the cage.

FIG. 3 depicts a front view of a network interface card similar to the network interface card from FIG. 1.

FIG. 4 depicts a front view of a network interface card, similar to the front view described with reference to FIG. 3, which includes a coldplate.

FIG. 5 is a side view of an example of a network interface card that includes a coldplate that has a receiving channel that is disposed over a cage of a network interface.

FIG. 6A is a top cutaway view of an example of a coldplate.

FIG. 6B is a perspective view of a module inserted within a cage with the receiving channel of the coldplate disposed over the cage.

FIG. 7A is a front view of a body of a coldplate that shows bounds of the receiving channel.

FIG. 7B is a bottom view of the body from FIG. 7A that shows bounds of the receiving channel.

FIG. 8A is a top perspective view of a top piece and a bottom piece of a coldplate in which the top piece and the bottom piece are shown separated from each other.

FIG. 8B is a bottom perspective view of the top piece and the bottom piece of the coldplate from FIG. 8A in which the top piece and the bottom piece are again shown separated from each other.

FIG. 9A is a top perspective view of a coldplate similar to the perspective view of FIG. 8A in which the top piece and the bottom piece of the coldplate are attached to each other.

FIG. 9B is a cross sectional view of the coldplate of FIG. 9A at section A-A.

FIG. 10 is a perspective cross sectional view of an OSFP module inserted within an OSFP cage with the receiving channel of the coldplate disposed over the OSFP cage and over the OSFP module that is inserted within the OSFP cage.

FIG. 11 is a bottom view that shows a coldplate, a cage, and a pluggable module inserted into the cage.

Throughout the description, similar reference numbers may be used to identify similar elements.

### DETAILED DESCRIPTION

It will be readily understood that the components of the examples as generally described herein and illustrated in the appended figures could be arranged and designed in a wide variety of different configurations. Thus, the following more detailed description of various examples, as represented in the figures, is not intended to limit the scope of the present disclosure, but is merely representative of various examples. While the various aspects of the examples are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present disclosure should be or are in any single example. Rather, language referring to the features and advantages is understood to mean that a specific feature, advantage, or characteristic described in connection with an example is included in at least one example of the present disclosure. Thus, discussions of the features and advantages, and similar language, throughout this specification may, but do not necessarily, refer to the same example.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain examples that may not be present in all examples of the invention.

Reference throughout this specification to “one example”, “an example”, or similar language means that a particular feature, structure, or characteristic described in connection with the indicated example is included in at least one embodiment of the present invention. Thus, the phrases “in one example”, “in an example”, and similar language throughout this specification may, but do not necessarily, all refer to the same embodiment.

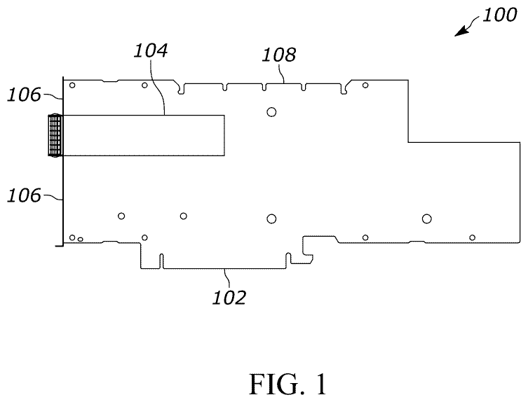

FIG. 1 is a side view of an example of a network interface card 100 that can be connected to another computer system (not shown) through a PCIe interface 102. In the example of FIG. 1, the network interface card occupies a single slot in the computer system and may be referred to as a 1-slot PCIe card. The network interface card also includes a network interface 104 accessible at a front plate 106 that enables the network interface card to be connected to a communications media such as optical fiber or copper wire. In an example, the network interface is configured to receive a pluggable module, such as a pluggable transceiver module, which can be inserted into, or removed from, the network interface of the network interface card by hand. The network interface of the network interface card may include a cage (not shown) that is attached to a circuit board 108 of the network interface card. In an example, the network interface and the pluggable module are compatible with a standard specification, such as the Optical Small Form Factor Pluggable (OSFP) Multi-Source Agreement (MSA). Although not shown in FIG. 1, the network interface card may include a housing, such as a metal housing that encases the circuit board and electronic components that are attached to the circuit board.

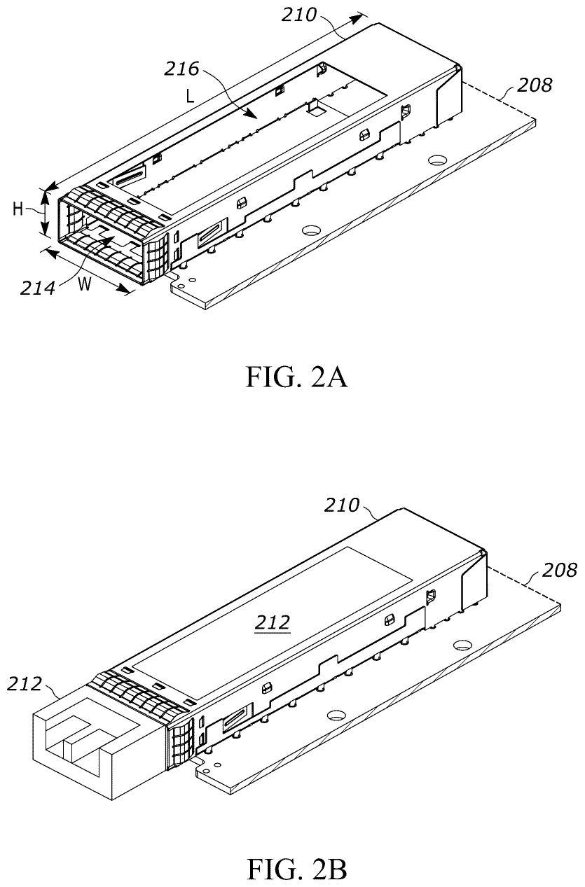

As described above, a pluggable module can be inserted into, or removed from, a network interface of a network interface card by hand. FIG. 2A is a perspective view of a cage 210 of a network interface that is attached to a circuit board 208 of a network interface card (not shown) and that can receive a pluggable module. In the example of FIG. 2A, the cage is shaped and sized to receive a pluggable module as is known in the field and as is specified by, for example, the OSFP specification. An example cage that conforms to the OSFP specification has a height dimension, H, of 11.15 mm, a width dimension, W, of 23.38 mm, and a length dimension, L, of 91 mm, although the dimensions may vary. In the example of FIG. 2A, the cage includes a frontside opening 214 to receive the pluggable module and a topside opening 216 that exposes a portion of the pluggable module when the pluggable module is inserted into the cage.

FIG. 2B is a perspective view of the cage 210 from FIG. 2A and a pluggable module 212 inserted into the cage. As shown in FIG. 2B, a portion of the pluggable module 212 is exposed at the opening 216 in the top side of the cage. The exposed portion of the pluggable module may be utilized for cooling. In some cases, the opening in the top side of the cage makes room for a Riding Heat Sink (RHS).

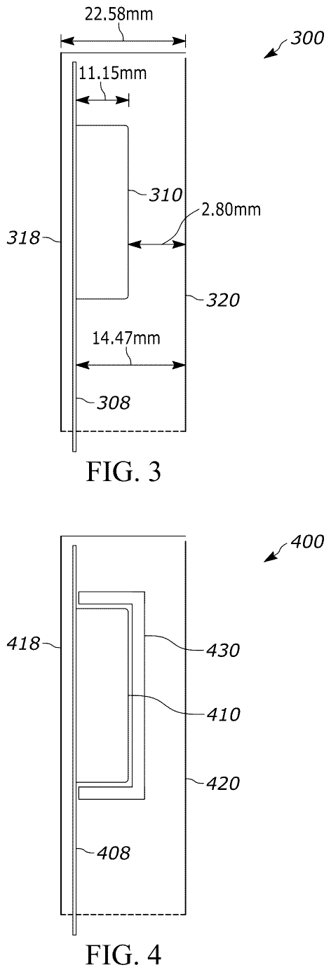

A network interface card such as a PCIe card may be configured to occupy only one slot in a computer system and may be referred to as a 1-slot PCIe card. FIG. 3 depicts a front view of a network interface card 300 similar to the network interface card 100 from FIG. 1, but without the front plate 106, which shows the circuit board 308, a cage 310 of the network interface, and a housing of the network interface card. In the example of FIG. 3, the housing includes a backside cover 318 (C-cover) and a frontside cover 320 (A-cover) that together encase the circuit board and various electronic components of the network interface card. Because the network interface card is designed to occupy only one slot in a computer system, the network interface card has a narrow width. As shown in FIG. 3, the network interface card has a width dimension of 22.58 mm and with the circuit board 308 positioned near the backside cover 318 as is typical, the distance between the circuit board 308 and the frontside cover 320 is a maximum of 14.47 mm. In a case in which the cage of the network interface has a height dimension of 11.15 mm, the space between the top side of the cage and the frontside cover is limited, e.g., to around 2.8 mm. Although some dimensions are provided, the dimensions are for example purposes and other dimensions are possible.

A drawback associated with PCIe cards that fit within 1-slot is insufficient cooling. The space constraints and limited air flow in computer devices and datacenters can cause passive cooling (e.g., heatsinks) to fail. Enclosed environments can also cause thinner active air cooling devices (e.g., fans) to fail. Other active air cooling devices do not fit within the space for a single slot. Heat pipes and other traditional liquid cooling devices do not fit within the space for a single PCIe slot. Liquid cooling can be applied to electronic components within network interface cards such as PCIe cards and liquid cooling of an electronic component can be accomplished via a coldplate through which a liquid flows to draw heat away from the electronic component. As described with reference to FIG. 3, the height of a network interface card, especially a 1-slot network interface card, results in a limited amount of space between components such as the top side of the cage of the network interface and the frontside cover of the network interface card. Although there is limited space between the top side of the cage and the frontside cover of the network interface card, it has been realized that there is space available around the sides of the cage that can be utilized in addition to the space between the top side of the cage and the frontside cover to implement liquid cooling.

In one or more embodiments, a coldplate that can be used to liquid cool an electronic component as described herein has a body with a top structure and a sidewall in which the top structure and the sidewall form a receiving channel that is disposed over an electronic component that is to be liquid cooled and in which the sidewall of the body includes a first opening, a second opening, and a sidewall conduit. Additionally, the sidewall conduit is configured to allow liquid to flow between the first opening and the second opening and the top structure includes multiple topside conduits that are configured to allow liquid to flow between the first opening and the second opening. When the coldplate is installed within a network interface card such as a 1-slot PCIe card, the coldplate fits in the limited space between the top side of the cage and the frontside cover of the network interface card and can provide adequate cooling to the electronic component while meeting structural integrity requirements. In an example, the topside conduits of the coldplate are small enough to fit in the limited space between the top side of the cage and the frontside cover of the network interface card and the sidewall conduit is large enough to maintain the pressure differential between the inlet and the outlet of the coldplate at an acceptable level. Additionally, ribs between the topside conduits ensure that the coldplate meets structural integrity requirements.

With the combination of a sidewall conduit and topside conduits integrated within the coldplate to convey liquid for thermal management of an electronic component, liquid is able to flow around a perimeter of the electronic component and over a top surface of the electronic component in a manner that adequately cools the electronic component while exhibiting an acceptable pressure differential between the inlet and the outlet of the coldplate. Additionally, ribs between the topside conduits of the coldplate provide the coldplate with a structural integrity that meets structural integrity requirements.

FIG. 4 depicts a front view of a network interface card 400, similar to the front view described with reference to FIG. 3, which includes a coldplate 430 that fits within the limited space between the top side of the cage 410 and the frontside cover 420 of the network interface card. In an example, there is a maximum of around 2.8 mm of space between the top side of the cage and the frontside cover for the coldplate. The coldplate has a top structure and a sidewall that form a receiving channel that is disposed over the cage of a network interface and the top structure is thin enough to fit within the limited space between the top of the cage and the frontside cover while providing adequate cooling to the electronic component and while meeting structural integrity requirements. In an example, the coldplate has a maximum height of about 1.8 mm, which enables the coldplate to fit within the 2.8 mm space that is between the top side of the cage and the frontside cover.

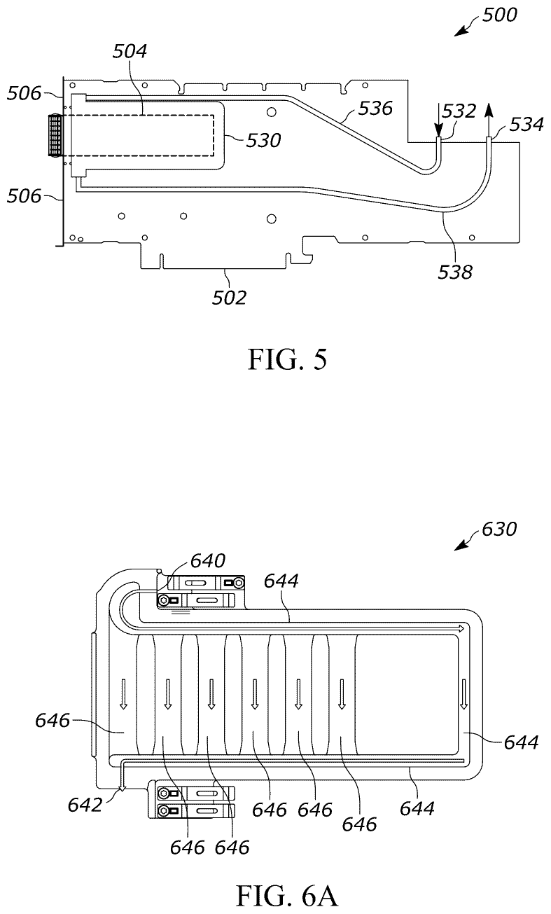

FIG. 5 is a side view of an example of a network interface card 500 that includes a coldplate 530 that has a receiving channel that is disposed over a cage of a network interface 504 as described with reference to FIG. 4. In an example operation, the network interface card is connected to a computer system (not shown) via the PCIe interface 502 and connected to an external liquid cooling system (not shown) by liquid interfaces. With reference to FIG. 5, the liquid interfaces of the network interface card include an inlet 532 to the network interface card and an outlet 534 from the network interface card. An inlet conduit 536 is connected between the inlet 532 and the coldplate 530 and an outlet conduit 538 is connected between the coldplate 530 and the outlet 534. Liquid can be circulated through the coldplate via the inlet, the inlet conduit, the outlet conduit, and the outlet.

It should be noted that while FIG. 5 is a side view of the network interface card 500, for purposes of this description, FIG. 5 is considered to also show a top view of the coldplate 530. That is, FIG. 5 shows a side view of the network interface card and a top view of the coldplate that is attached to the network interface card.

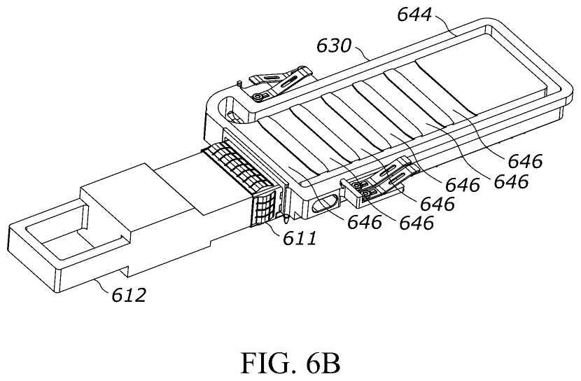

FIG. 6A is a top cutaway view of an example of a coldplate 630, similar to the coldplates 430 and 530 from FIGS. 4 and 5, respectively, which includes an inlet 640, an outlet 642, a sidewall conduit 644, and multiple topside conduits 646 of the coldplate. As shown in FIG. 6A, the coldplate may have a rectangular shape, the sidewall conduit is located around three sides of the coldplate, and the topside conduits extend from a first long side of the coldplate to a second long side of the coldplate, which is opposite the first long side. Arrows in FIG. 6A also illustrate the flow of liquid through the sidewall conduit and through the topside conduits of the coldplate. As illustrated by the arrows in FIG. 6A, liquid may flow in the sidewall conduit in a clockwise direction from the inlet to the outlet and liquid flows in the topside conduits across the coldplate from the inlet to the outlet. In an example, of all the liquid that enters the coldplate at the inlet and exits the coldplate at the outlet, a portion of the liquid flows through the sidewall conduit, a portion of the liquid flows through the topside conduits, and a portion of the liquid flows through at least a portion of the sidewall conduit and at least one of the topside conduits.

FIG. 6B is a perspective view of an OSFP module 612 inserted within an OSFP cage (only front end piece 611 is visible) with the receiving channel of the coldplate 630 disposed over the OSFP cage. In the example of FIG. 6B, the coldplate is shown with the top cutaway view of FIG. 6A to illustrate the liquid cooling conduits 644 and 646 relative to the electronic module when the electronic module is inserted within the cage.

In the example of FIGS. 6A and 6B, the coldplate 630 includes six topside 646 conduits although it should be understood that a different number of topside conduits is possible. Additionally, although a particular configuration of the six topside conduits is described with reference to FIGS. 6A and 6B, other configurations of the topside conduits are possible. For example, a coldplate may include topside conduits that span the entire length of the top structure.

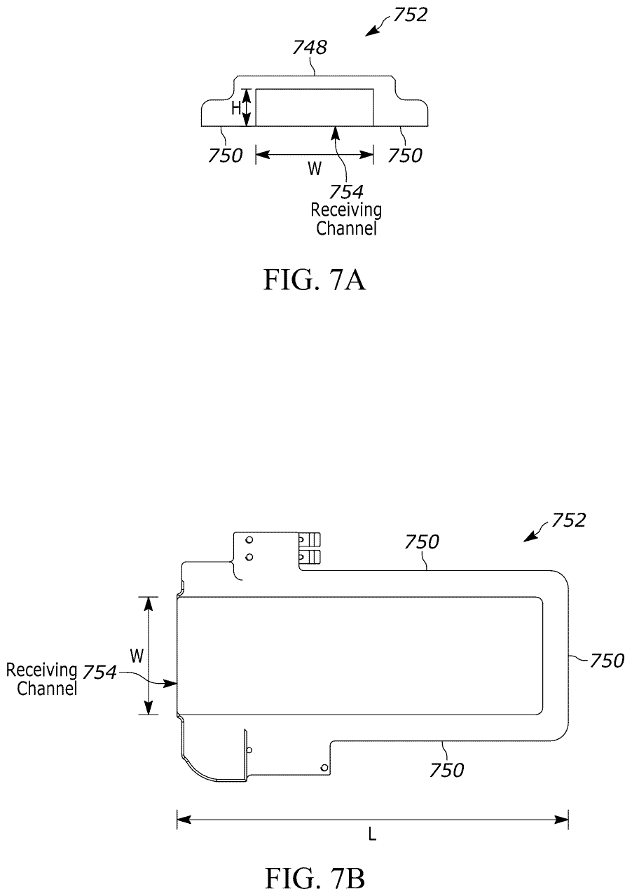

As described above, the top structure and the sidewall of the body of the coldplate form a receiving channel that fits over the electronic component and/or over the cage that is designed to house the electronic component. FIGS. 7A and 7B depict a top structure 748 and a sidewall 750 of a body 752 of a coldplate that together form a receiving channel 754. FIG. 7A is a front view of the body 752 that shows bounds of the receiving channel 754 from the perspective of the front view and FIG. 7B is a bottom view of the body 752 from FIG. 7A that shows bounds of the receiving channel 754 from the perspective of the bottom view. FIG. 7A also shows the height dimension, H, and the width dimension, W, of the receiving channel while FIG. 7B shows the width dimension, W, and the length dimension, L, of the receiving channel.

In an example, the receiving channel of the coldplate is configured to fit over a cage within which the electronic component is to be housed in that the dimensions of the receiving channel enable the receiving channel to mate with, or be coupled with, the corresponding cage. In an example, the receiving channel of the coldplate can mate or couple with the cage if the width dimension of the receiving channel is about 0.5 mm (±10% or ±0.1 mm) larger than the width of the cage. In the case in which the cage is an OSFP cage with a width of 23.38 mm, the receiving channel of the coldplate has a width of about 23.88 mm (±10% or ±0.1 mm) so that the receiving channel of the coldplate can mate or couple with the OSFP cage. In an example, the width of the receiving channel is designed so that the receiving channel fits snugly around the two long sides of the cage. In an example, the coldplate is also designed so that the receiving channel abuts against the back (closed) end of the cage and the open end of the receiving channel extends to the front (open) end of the cage. In some cases, the network interface may include an additional element such as a plastic front end piece at the front (open) end of the cage, such as the plastic front end piece 611 shown in FIG. 6B.

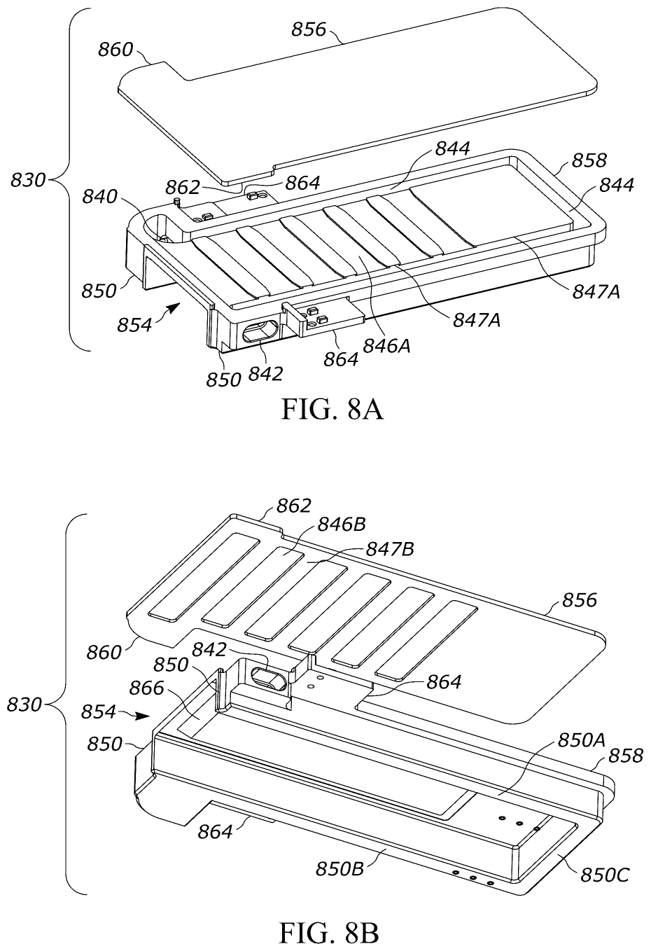

In an example, the coldplate may include two separate pieces that are attached to each other. For example, the coldplate may be produced by separately machining a first metal piece (e.g., a bottom piece) and a second metal piece (e.g., a top piece) and then soldering the first and second metal pieces together. FIG. 8A is a top perspective view of a top piece 856 and a bottom piece 858 of a coldplate 830 in which the top piece and the bottom piece are shown separated from each other. A completed coldplate includes the top piece and bottom piece attached (e.g., soldered) to each other.

Elements of the top piece 856 of the coldplate that are visible in FIG. 8A include a top surface of a generally rectangular thin planar piece of metal that is shaped to match the shape of the bottom piece and that includes an inlet feature 860 and an outlet feature 862. In the example, the inlet feature is an inlet wing that extends from a first long edge of the top piece and the outlet feature is an outlet wing that extends from a second long edge of the top piece. In an example, the top piece may be about 1.0 mm thick (±10% or ±0.1 mm).

Elements of the bottom piece 858 of the coldplate 830 that are visible in FIG. 8A include an inlet 840, a sidewall conduit 844, bottom portions of six topside conduits 846A, bottom portions of six ribs 847A, an outlet 842, and a front opening of the receiving channel 854. Note that only one of the bottom portions of the six topside conduits 846A and only one of the bottom portions of the six ribs 847A are labeled with reference numbers to avoid excess clutter in the figure.

In the example of FIG. 8A, the sidewall conduit 844 is a cavity that has been formed in the bottom piece 858 and that circumvents three sides of the bottom piece that form the sidewall. In an example, the sidewall conduit is a cavity that extends into the sidewall to below a level of the bottom portions of the topside conduits 846A and at least to a level of the inlet 840 and the outlet 842. The bottom portions of the six topside conduits 846A are cavities that have been formed in the bottom piece. The cavity of the sidewall conduit and the cavities of the six topside conduits may be cavities that are machined into the bottom piece. In an example, the topside cavities may have a depth of 0.9 mm and the sidewall conduit may have a depth of 8.0 mm.

As shown in FIG. 8A, the inlet 840 is formed in a portion of the sidewall 850 that extends out from the bottom piece 858 to form an inlet reservoir. In the example, the inlet 840 is an opening in a portion of the sidewall that is orthogonal to the long sides of the coldplate and parallel to the ends of the coldplate. The outlet 842 is an opening formed in the sidewall at a long side of the top structure that is opposite to the inlet. In the example, the outlet is an opening in a portion of the sidewall that is near the open end of the receiving channel. Referring briefly back to FIG. 5, a portion of the inlet conduit 536 runs parallel to the long sides of the coldplate 530 and is attached to the inlet of the coldplate and a portion of the outlet conduit 538 is orthogonal to long the sides of the coldplate and is attached to the outlet of the coldplate. Referring back to FIG. 8A, although one configuration of the inlet 840 and outlet 842 is described herein, the inlet and outlet may have different configurations. In an example, the inlet and outlet should be located at opposite ends of the sidewall conduit so that at least some of the liquid flows from the inlet to the outlet through the entire sidewall conduit.

FIG. 8A also shows attachment features 864 that may be included with the coldplate. In an example, the attachment features are metal pads at the long sides of the bottom piece 858 to which clips can be attached. The metal pads may be machined as part of the coldplate or attached (e.g., soldered) to the coldplate. For example, the metal pads may be machined as part of the bottom piece or attached (e.g., soldered) to the bottom piece. In an example, clips are attached to the metal pads and the clips are used to secure the coldplate within a network interface card.

FIG. 8B is a bottom perspective view of the top piece 856 and the bottom piece 858 of the coldplate 830 from FIG. 8A in which the top piece and the bottom piece are again shown separated from each other. A completed coldplate includes the top and bottom pieces attached (e.g., soldered) to each other.

Elements of the top piece 856 that are visible in FIG. 8B include a bottom surface of the top piece, top portions of the six topside conduits 846B, top portions of the six ribs 847B, the inlet feature 860, and the outlet feature 862. Note that only one of the top portions of the six topside conduits 846B and only one of the top portions of the six ribs 847B are labeled with reference numbers to avoid excess clutter in the figure. In the example of FIG. 8B, the top portions of the six topside conduits 846B are cavities that have been formed in the top piece. The cavities may be machined depressions at the bottom surface of the top piece. For example, the cavities may be about 0.6 mm deep. The strips of material of the top piece that remain between the topside conduits are the top portions of the ribs 847B. In an example, the cavities in the top piece are separated by the ribs to ensure adequate structural integrity of the top structure once the top piece and the bottom piece are attached to each other. In the example of FIGS. 8A and 8B, the shapes, sizes, and locations of the cavities on the top piece and on the bottom piece are complementary to each other and together form the topside conduits when the top piece and the bottom piece are attached to each other.

Elements of the bottom piece 858 that are visible in FIG. 8B include, a pedestal 866, the sidewall 850, the outlet 842, and the attachment features 864. The receiving channel 854 that is formed by the bottom surface and the sidewall of the bottom piece is also visible in FIG. 8B.

As shown in FIG. 8B, the pedestal 866 at the bottom surface of the bottom piece (e.g., the bottom surface of the top structure of the body) extends along a portion of the bottom surface of the bottom piece. In an example, the location of the pedestal corresponds to an opening in a cage of the network interface. When an electronic component is inserted into the cage, the pedestal brings a portion of the coldplate into close proximity to the electronic component.

As shown in FIG. 8B, the sidewall 850 of the rectangular shaped bottom piece extends down from three sides of the rectangular shaped bottom piece 858. A first portion of the sidewall 850A extends down from a first long side of the bottom piece, a second portion of the sidewall 850B extends down from a second long side of the bottom piece (opposite the first long side), and a third portion of the sidewall 850C extends down from an end of the bottom piece. The bottom surface and the sidewall of the bottom piece 858 together form the receiving channel. In an example, the receiving channel is designed to mate or couple with a cage, e.g., an OSFP cage, of a network interface.

In the example described with reference to FIGS. 8A and 8B, topside conduits formed by the top and bottom pieces 856 and 858, respectively, are aligned with the pedestal 866 to provide fluid flow at an area of the coldplate that is in close proximity to the source of heat, e.g., the electronic component. Additionally, the widest rib 847A that is at the closed end of the receiving channel 854 is aligned with an area of the bottom piece that does not include the pedestal. In an example, the widest rib creates a large surface area of contact between the corresponding portions of the top and bottom pieces to enhance structural integrity of the coldplate. Although the coldplate is described as having a pedestal, in some examples, the coldplate may not include a pedestal.

As described with reference to FIGS. 8A and 8B, the top structure and/or the sidewall of the coldplate 830 may be formed in part by the top piece 856 and the bottom piece 858 once the top piece and the bottom piece are attached to each other, e.g., by soldering. When viewed together, FIGS. 8A and 8B show that the perimeter and the ribs of the top and bottom pieces align with each other and are complimentary surfaces that can be soldered together to form the coldplate. If the size of any of the topside conduits are too large, the structural integrity of the coldplate may be compromised to the point that the coldplate may not meet structural integrity requirements. In an example, the number and size of the topside conduits is a balance between providing a large enough surface area over which liquid can flow and ensuring structural integrity of the coldplate. For example, if the six separate topside conduits were formed as a single topside conduit that did not include any ribs, the coldplate may not meet structural integrity requirements. In an example, the topside conduits are each 6 mm wide, the five small ribs are 4.0 mm wide, and the one large rib is 23.75 mm wide.

As shown in the examples of FIGS. 8A and 8B, the sidewall extends down from three sides of the top structure, e.g., first portion 850A, second portion 850B, and third portion 850C. Further, it can be seen from FIGS. 8A and 8B that the sidewall conduit 844 in the first and second portions (850A and 850B) of the sidewall are parallel to each other and orthogonal to the topside conduits (e.g., formed by 846A and 846B). The orthogonality of portions of the sidewall conduit and the topside conduits enables liquid to contact a large surface area of the coldplate that is in close proximity to the electronic component.

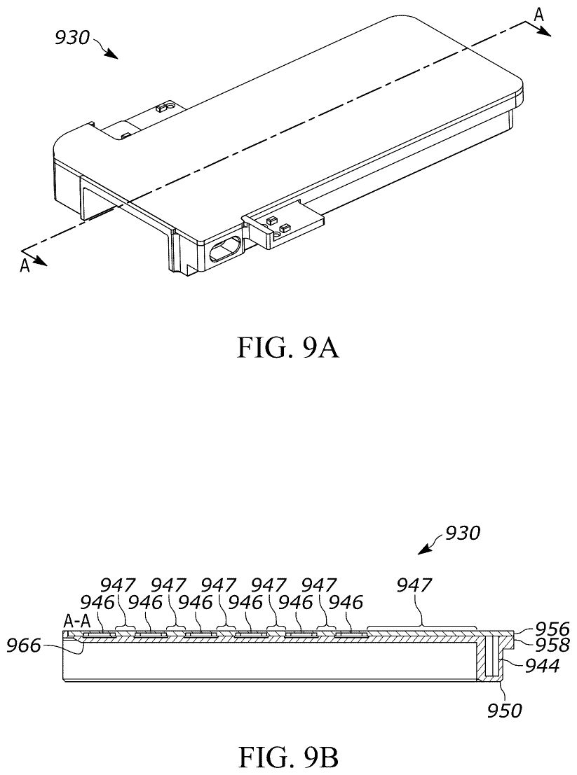

FIG. 9A is a top perspective view of the coldplate 930 similar to the perspective view of FIG. 8A in which the top piece and the bottom piece of the coldplate are attached to each other.

FIG. 9B is a cross sectional view of the coldplate 930 of FIG. 9A at section A-A. Elements of the coldplate that are visible in the cross sectional view of FIG. 9B include the top piece 956, the bottom piece 958, the topside conduits 946, the ribs 947, the pedestal 966, the sidewall 950, and the sidewall conduit 944. In the cross sectional view of FIG. 9B, it can be seen that the topside conduits 946 have a small height to width ratio (e.g., on the order of 0.9/6) in comparison to the height to width ratio of the sidewall conduit 944 (e.g., on the order of 8/2.6). In the example, the differences in height to width ratios correspond to the orientation of the conduits relative to the heat source so that a large surface area of both the topside conduits and the sidewall conduit is exposed to the heat source to provide a large surface area for heat transfer from the electronic component to the liquid. Additionally, as shown in the example of FIG. 9B, the cross sectional area of the sidewall conduit is much larger than the cross sectional area of each topside conduit, e.g., on the order of 3.85 times larger (sidewall conduit: 8×2.6=20.8 mm² vs. topside conduit: 0.9×6=5.4 mm²). The larger cross sectional area of the sidewall conduit helps to provide a pressure differential across the coldplate that is acceptable in the environment in which the network interface card is installed. In an example, a balance is struck between the relative cross sectional areas of the topside conduits and the sidewall conduit. Due to fluid dynamics, if the cross sectional area of the sidewall conduit is too large relative to the cross sectional area of the topside conduits, not enough liquid may flow through the topside conduits, which can reduce the effectiveness of the liquid cooling.

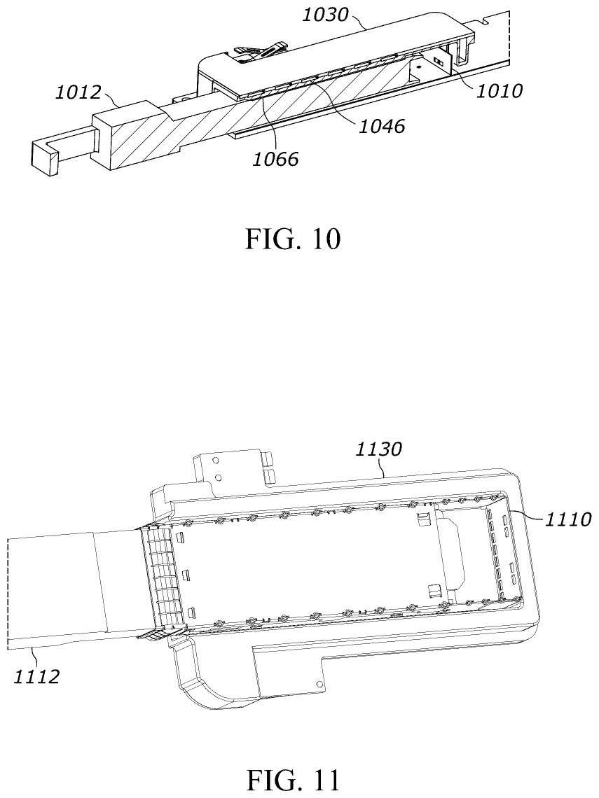

FIG. 10 is a perspective cross sectional view of an OSFP module 1012 inserted within an OSFP cage 1010 with the receiving channel of the coldplate 1030 disposed over the OSFP cage and over the OSFP module that is inserted within the OSFP cage. As can be seen in the example of FIG. 10, at least a portion of the top structure of the coldplate is in close proximity to the OSFP module. In particular, the pedestal 1066 of the top structure is extremely close to the OSFP module and may be in direct contact with the portion of the OSFP module that is exposed through the opening in the cage. Additionally, it can be seen that the six topside conduits 1046 have a large surface area that is facing, and in close proximity to, the top surface of the OSFP module, which can help with heat transfer from the OSFP module to the liquid that flows through the topside conduits.

FIG. 11 is a bottom view that shows a coldplate 1130, a cage 1110, and a pluggable module 1112 inserted into the cage. The bottom view of FIG. 11 does not show a circuit board to which the cage would be connected so that the relationship between the receiving channel of the coldplate, the cage, and the pluggable module can be better illustrated. As shown in FIG. 11, the receiving channel of the coldplate fits over the cage such that surfaces of the receiving channel are in close proximity to the cage and thus in close proximity to the electronic component that is inserted into the cage. In particular, the dimensions of the receiving channel are such that the receiving channel fits snugly around the three sides of the cage.

As described herein, the sidewall of the coldplate is adjacent to the sides of the cage within which the electronic component is inserted. In the example shown in FIG. 11, the sidewall covers nearly all of the sides of the cage on three sides of the cage. In other examples, the sidewall of the coldplate may cover more or less of the sides of the cage. The design of the coldplate takes advantage of available space around the sides of the cage to promote the flow of liquid while also exposing enough liquid to a top side of the electronic component to promote adequate heat transfer between the electronic component and the liquid.

In the example described with reference to FIG. 4, the network interface card includes a housing with a frontside cover and a backside cover that encase the circuit board and the cage. However, in other examples, the network interface card may include only a frontside cover or a backside cover, or the network interface card may not include a housing. Regardless of whether or not the network interface card includes a housing, the network interface card may be subjected to similar width limitations due to adjacent network interface cards and/or other components of the computer system within which the network interface card is installed. In addition, although one example of the network interface card is a PCIe card, the network interface card may be compatible with some other serial bus interface that, for example, provides an interface to a motherboard. Additionally, although the design of the coldplate as disclosed herein is particularly applicable to a 1-slot network interface card, the coldplate may be used in other liquid cooling applications where similar space limitations exist. Further, the same design principles could be applied to a coldplate that is disposed over an electronic component that is not within a cage, e.g., that is not pluggable by hand. For example, the electronic component could be soldered directly to the circuit board and the coldplate could be positioned directly over the electronic component with no other structure, such as a cage, between the electronic component and the coldplate.

Although some specific dimensions are described herein, it should be understood that other dimensions are possible. Additionally, in some examples, dimensions that are specified herein may be considered to vary from the stated dimensions within some margin of, for example, ±5% of the stated dimension, ±10% of the stated dimension, or ±20% of the stated dimension.

The term “coupled” or similar language may include a direct physical connection or a connection through other intermediate components even when those intermediate components change the form of coupling from source to destination.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific examples have been described and illustrated, the invention is not to be limited to the specific forms or arrangements of parts so described and illustrated. The scope of the invention is to be defined by the claims appended hereto and their equivalents.

What is claimed is:

1. A coldplate apparatus comprising:
a body having a top structure and a sidewall, wherein the top structure and the sidewall form a receiving channel configured to be disposed over an electronic component;
wherein the sidewall of the body includes a first opening, a second opening, and a sidewall conduit, wherein the sidewall conduit is configured to allow liquid to flow between the first opening and the second opening; and
wherein the top structure includes a plurality of topside conduits that are configured to allow liquid to flow between the first opening and the second opening.

2. The coldplate apparatus of claim 1, wherein the top structure is a rectangular top structure and the sidewall extends down from three edges of the rectangular top structure to form the receiving channel.

3. The coldplate apparatus of claim 2, wherein:
the sidewall includes a first side portion, a second side portion, and an end portion; and
at least one of the plurality of topside conduits connects the sidewall conduit in the first side portion of the sidewall to the sidewall conduit in the second side portion of the sidewall.

4. The coldplate apparatus of claim 3, wherein the sidewall conduit in the first side portion of the sidewall and the sidewall conduit in the second side portion of the sidewall are parallel to each other and orthogonal to the plurality of topside conduits.

5. The coldplate apparatus of claim 3, wherein the receiving channel is rectangular in shape, closed on three sides, and open on one side.

6. The coldplate apparatus of claim 5, wherein the first opening in the sidewall and the second opening in the sidewall are located at an end of the coldplate that corresponds to the open side of the receiving channel.

7. The coldplate apparatus of claim 1, wherein at least some of the topside conduits are separated by one or more ribs of the top structure.

8. The coldplate apparatus of claim 1, wherein the electronic component is a rectangular shaped electronic component.

9. The coldplate apparatus of claim 1, wherein the electronic component is a pluggable transceiver module, and wherein the receiving channel is configured to be disposed over a cage that receives the pluggable transceiver module.

10. The coldplate apparatus of claim 9, wherein the pluggable transceiver module is an Octal Small Form Factor Pluggable (OSFP) transceiver module, and the cage is an OSFP cage.

11. The coldplate apparatus of claim 9, wherein:
the cage includes an opening at a top surface; and
the top structure of the body includes a pedestal on a bottom surface of the top structure that fits within the opening at the top surface of the cage.

12. The coldplate apparatus of claim 11, wherein at least some of the topside conduits are separated by one or more ribs of the top structure, wherein the topside conduits are only positioned above the pedestal.

13. The coldplate apparatus of claim 1, wherein the receiving channel formed by the body and sidewall is coupled with a cage of a network interface.

14. The coldplate apparatus of claim 1, wherein the top structure of the body has a maximum height of about 1.8 millimeters.

15. The coldplate apparatus of claim 1, wherein the body includes a bottom piece attached to a top piece.

16. A coldplate apparatus for performing thermal management of a pluggable electronic component comprising:
a body having a top structure and a sidewall, wherein the top structure and the sidewall form a receiving channel configured to be disposed over at least three sides of a cage that is configured to receive the pluggable electronic component;
wherein the sidewall of the body includes a first opening, a second opening, and a sidewall conduit that is configured to allow liquid to flow between the first opening and the second opening; and
wherein the top structure includes a plurality of topside conduits that are configured to allow liquid to flow between the first opening and the second opening.

17. The coldplate apparatus of claim 16, wherein the sidewall is configured to be coupled with two sidewalls of the cage and the top structure is configured to be coupled with a top of the cage.

18. The coldplate apparatus of claim 17, wherein the cage is an Octal Small Form Factor Pluggable (OSFP) cage.

19. A network interface card comprising:
a circuit board;
a serial bus interface coupled to the circuit board;
a cage attached to the circuit board and configured to receive a pluggable electronic component;
a coldplate including a body having a rectangular top structure and a sidewall extending down from three edges of the top structure, wherein the top structure and the sidewall form a receiving channel to couple with the cage;
wherein the sidewall of the body includes a first opening, a second opening, and a sidewall conduit that is configured to allow liquid to flow between the first opening and the second opening; and
wherein the top structure includes a plurality of topside conduits that are configured to allow liquid to flow between the first opening and the second opening.

20. The network interface card of claim 19, wherein the cage is an Octal Small Form Factor Pluggable (OSFP) cage.
